(19) United States
(12) Patent Application Publication
(10) Pub. No.: US 2022/0397819 A1
(43) Pub. Date: Dec. 15, 2022

(54) BLANK MASK AND PHOTOMASK USING THE SAME

(71) Applicant: SKC solmics Co., Ltd., Pyeongtaek-si (KR)

(72) Inventors: GeonGon LEE, Seoul (KR); Suk Young CHOI, Seoul (KR); Hyung-joo LEE, Seoul (KR); Suhyeon KIM, Seoul (KR); SUNG HOON SON, Seoul (KR); Seong Yoon KIM, Seoul (KR); Min Gyo JEONG, Seoul (KR); Hahyeon CHO, Seoul (KR); Taewan KIM, Seoul (KR); INKYUN SHIN, Seoul (KR)

(73) Assignee: SKC solmics Co., Ltd., Pyeongtaek-si (KR)

(21) Appl. No.: 17/834,279

(22) Filed: Jun. 7, 2022

(30) Foreign Application Priority Data
Jun. 8, 2021 (KR) 10-2021-0074221

(51) Int. Cl. G03F 1/32

(52) U.S. Cl. CPC G03F 1/32

(57) ABSTRACT

A blank mask including: a transparent substrate and a light shielding film disposed on the transparent substrate, wherein the light shielding film includes a transition metal and at least one of oxygen and nitrogen, and wherein the light shielding film has an SA1 value of 60 to 90 mN/m according to Equation 1-1:

SA1=γ_{SL}×tan θ [Equation 1-1]

where, in the Equation 1-1, the γ_{SL} is an interfacial energy between the light shielding film and a pure water and θ is a contact angle of the light shielding film measured with the pure water, is disclosed.

### CROSS-REFERENCE TO RELATED APPLICATIONS

This application claims the benefit under 35 U.S.C. 119(a) of Korean Patent Application No. 10-2021-0074221 filed on Jun. 8, 2021 in the Korean Intellectual Property Office, the entire disclosure of which is incorporated herein by reference for all purposes.

### BACKGROUND

### 1. Field

The present disclosure relates to a blank mask and a photomask using the same.

### 2. Description of Related Art

Due to high integration of semiconductor devices or the like, miniaturization of circuit patterns of semiconductor devices is being required. For this reason, importance of a lithography technique, which is a technique for developing a circuit pattern on a wafer surface using a photomask, is being further emphasized.

To develop a miniaturized circuit pattern, a light source of exposure light used in an exposure process (photolithography) is required to have a short wavelength. Recently, as the light source of exposure light, ArF excimer laser (wavelength of 193 nm) or the like is used.

Meanwhile, Binary mask, Phase shift mask, and the like are used as photomasks.

The Binary mask has a structure, in which a light shielding pattern layer is formed on a transparent substrate. On a surface, where a pattern is formed from the Binary mask, a transmissive portion not including a light shielding layer allows exposure light to be transmitted, and a light shielding portion including a light shielding layer shields exposure light, to transfer a pattern on resist film of a surface of a wafer. However, the Binary mask may cause a problem in developing a minute pattern due to diffraction of light occurring at an edge of the transmissive portion as the pattern is more miniaturized.

As a phase shift mask, Levenson type, Outrigger type, and Half-tone type are used. Among the above, Half-tone type phase shift mask has a structure, in which a pattern formed with semi-transmissive films, is formed on a transparent substrate. On a surface, where a pattern is formed from the Half-tone type phase shift mask, a transmissive portion not including a semi-transmissive layer allows exposure light to be transmitted, and a semi-transmissive portion including a semi-transmissive layer allows exposure light to be attenuated. The attenuated exposure light is allowed to have a phase difference compared to exposure light, which has transmitted the transmissive portion. Accordingly, diffraction light occurring at an edge of the transmissive portion is counteracted by the exposure light, which has transmitted the semi-transmissive portion, and thereby the phase shift mask can form a further refined minute pattern on the surface of a wafer.

### SUMMARY

A blank mask according to one embodiment of the present disclosure may include a transparent substrate and a light shielding film disposed on the transparent substrate, wherein the light shielding film may include a transition metal and at least one of oxygen and nitrogen, and wherein the light shielding film may have an SA1 value of 60 to 90 mN/m according to Equation 1-1:

SA1=γ_{SL}×tan θ [Equation 1-1]

where, in the Equation 1-1, γ_{SL} is an interfacial energy between the light shielding film and a pure water and θ is a contact angle of the light shielding film measured with the pure water.

The θ may be 70° or more.

The γ_{SL} may be 22 mN/m or more.

The light shielding film may have a surface energy of 42 to 47 mN/m.

The light shielding film may have a ratio of 0.135 to 0.16 for polar component of the surface energy compared to the surface energy of the light shielding film.

The light shielding film may include a first light shielding layer and a second light shielding layer disposed on the first light shielding layer.

An amount of the transition metal of the second light shielding layer may be greater than an amount of the transition metal of the first light shielding layer.

The transition metal may include at least one selected from the group consisting of Cr, Ta, Ti, and Hf.

A blank mask according to another embodiment of the present disclosure may include a transparent substrate, a phase shift film disposed on the transparent substrate, and a light shielding film disposed on the phase shift film, wherein the phase shift film may include a transition metal and silicon, wherein the light shielding film may include a transition metal and at least one of oxygen and nitrogen, and wherein a contact angle of the light shielding film measured with a pure water is 70° or more.

The γ_{SL} may be 22 mN/m or more.

The light shielding film may have a surface energy of 42 to 47 mN/m.

The light shielding film may have a ratio of 0.135 to 0.16 for polar component of the surface energy compared to the surface energy of the light shielding film.

The light shielding film may include a first light shielding layer and a second light shielding layer disposed on the first light shielding layer.

An amount of the transition metal of the second light shielding layer may be greater than an amount of the transition metal of the first light shielding layer.

The transition metal may include at least one selected from the group consisting of Cr, Ta, Ti, and Hf.

A photomask according to another embodiment may include a transparent substrate and a light shielding pattern film disposed on the transparent substrate, wherein the light shielding pattern film may include a transition metal, and at least one of oxygen and nitrogen, and wherein the light shielding pattern film may have a PSA1 value of 60 to 90 mN/m according to Equation 3 below:

PSA1=γ_{PSL}×tan θ_{P} [Equation 3]

where, in the Equation 3, the γ_{PSL} is an interface energy between an upper surface of the light shielding pattern film and the pure water and θ_{P} is a contact angle of the upper surface of the light shielding pattern film measured with the pure water.

The light shielding film may include a first light shielding layer and a second light shielding layer disposed on the first light shielding layer.

An amount of the transition metal of the second light shielding layer may be greater than an amount of the transition metal of the first light shielding layer.

The transition metal may include at least one selected from the group consisting of Cr, Ta, Ti, and Hf.

Other features and aspects will be apparent from the following detailed description and the claims.

### BRIEF DESCRIPTION OF THE DRAWINGS

FIG. 1 is a conceptual view for illustrating a blank mask according to one embodiment of the present disclosure.

FIG. 2 is a conceptual view for illustrating a blank mask according to another embodiment of the present disclosure.

FIG. 3 is a conceptual view for illustrating a blank mask according to another embodiment of the present disclosure.

FIG. 4 is a conceptual view for illustrating a photomask according to another embodiment of the present disclosure.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of this disclosure. For example, the sequences of operations described herein are merely examples, and are not limited to those set forth herein, but may be changed as will be apparent after an understanding of this disclosure, with the exception of operations necessarily occurring in a certain order. Also, descriptions of features that are known in the art may be omitted for increased clarity and conciseness.

In this disclosure, the term for degree like “about”, “substantially” and the like is used for meaning values approximative from/to the value when a tolerance to be proper to referred meaning for manufacture and substance is presented. Additionally, these terms for degree are used to help understanding of example embodiments and to prevent that an unconscionable trespasser unjustly uses the presented content in which exact or absolute number is referred.

Throughout this disclosure, the phrase “combination(s) thereof” included in a Markush-type expression denotes one or more mixtures or combinations selected from the group consisting of components stated in the Markush-type expression, that is, denotes one or more components selected from the group consisting of the components are included.

Throughout this disclosure, the description of “A and/or B” means “A, B, or A and B.”

Throughout this disclosure, terms such as “first”, “second”, “A”, or “B” are used to distinguish the same terms from each other unless specially stated otherwise.

In this disclosure, “B being placed on A” means that B is placed in direct contact with A or placed over A with another layer or structure interposed therebetween and thus should not be interpreted as being limited to B being placed in direct contact with A.

In this disclosure, a singular form is contextually interpreted as including a plural form as well as a singular form unless specially stated otherwise.

In this disclosure, room temperature refers to 20 to 25° C.

In this disclosure, a surface profile of a light shielding pattern film means an outline of a light shielding pattern film observed in the section thereof.

In this disclosure, a side surface profile of a light shielding pattern film means an outline of the side surface of the light shielding pattern film observed in the section thereof, when the section of the light shielding pattern film is observed by using TEM (Transmission Electron Microscopy) and the like.

Due to high integration of semiconductor devices, a further miniaturized circuit pattern is required to be formed on a semiconductor wafer. As a critical dimension (CD) of a pattern developed on a semiconductor wafer is further decreased, issues related to the resolution of a photomask is on an increasing trend.

For a light shielding film included in a blank mask, a cleaning process using a cleaning solution with a relatively high polarity may be performed to remove particles and the like after the film formation. In detail, a surface of the light shielding film may be irradiated by a UV light for increasing compatibility between the surface of the light shielding film and the cleaning solution, temporarily. Subsequently, while a blank mask is rotated, a cleaning solution may be injected to the surface of the light shielding film. When the particles and the like present on the surface of the light shielding film are not sufficiently removed through the cleaning process, the particles may become one cause of degrading the resolution of a blank mask. Additionally, when the cleaning solution remaining on the surface of the light shielding film is not removed enough after a cleaning process, the surface of the light shielding film may be damaged.

Inventors of the present disclosure verified that cleaning effect of a light shielding film can be improved and the damage of the light shielding film caused from a remaining cleaning solution can be effectively suppressed through a method of controlling compatibility between the surface of the light shielding film and polar molecules, and thereby completed the present disclosure.

Hereinafter, the present disclosure will be described in detail.

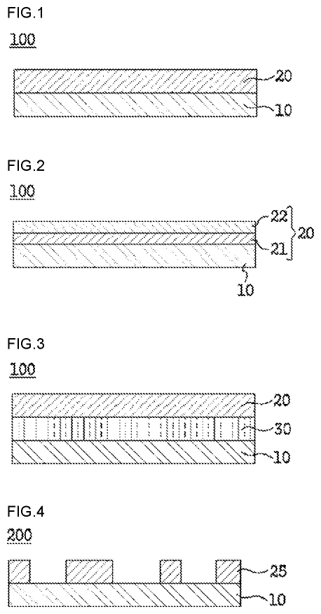

FIG. 1 is a conceptual view for illustrating a blank mask according to one embodiment of the present disclosure. With reference to the FIG. 1, the blank mask of the present disclosure is described.

A blank mask 100 includes a transparent substrate 10 and a light shielding film 20 disposed on the transparent substrate 10.

A material of the transparent substrate 10 is not limited if the material has light transmitting property with respect to an exposure light and can be applied to a blank mask 100. Specifically, the transmittance of the transparent substrate 10 with respect to an exposure light with wavelength of 193 nm may be 85% or more. The transmittance may be 87% or more. The transmittance may be 99.99% or less. For example, the transparent substrate 10 may be a synthetic quartz substrate. In such a case, the transparent substrate 10 can suppress attenuation of the light transmitting the transparent substrate 10.

In addition, surface characteristics such as smoothness and roughness of the transparent substrate 10 can be adjusted to suppress optical distortion.

A light shielding film 20 may be disposed on the top side of the transparent substrate 10.

The light shielding film 20 may have shielding characteristics against at least some of the exposure light transmitting the transparent substrate 10. Additionally, when a phase shift film 30 (refer to FIG. 3) and the like is disposed between the transparent substrate 10 and the light shielding film 20, the light shielding film 20 can be used as an etching mask in a process of etching the phase shift film 30 and the like to have a pattern shape.

The light shielding film 20 includes a transition metal and at least one of oxygen and nitrogen.

Characteristics Related to Surface Energy of Light shielding Film

The light shielding film 20 has an SA1 value of 60 to 90 mN/m according to Equation 1-1 below:

SA1=γ_{SL}×tan θ [Equation 1-1]

In the Equation 1-1, the γSL is an interfacial energy between the light shielding film 20 and a pure water, and the θ is a contact angle of the light shielding film 20 measured with a pure water.

Compatibility of the light shielding film 20 with respect to a polar solution is one of important factors, which can affect cleaning effect of the light shielding film 20. A cleaning solution applied to the cleaning of the light shielding film 20 is a solution made by mixing ammonia, hydrogen peroxide, and the like with water, and the solution has a relatively high polarity. When a surface of the light shielding film 20 is cleaned by such a polar solution, result of cleaning may be different depending on compatibility of the light shielding film 20 with respect to the polar solution.

Before performing cleaning of the light shielding film 20, a light with a high energy such as UV light may be irradiated to the surface of the light shielding film 20 for increasing compatibility of the light shielding film 20 with respect to a polar solution. In detail, bond between atoms present on the surface of the light shielding film 20 can be partially broken by irradiating a light with a high energy to the surface of the light shielding film 20. In addition, hydroxy radicals formed from oxygen gas or ozone included in the atmosphere may be formed by the light with a high energy. When the surface of the light shielding film 20 reacts with the radicals, a polar functional group may be formed on the surface of the light shielding film 20, and compatibility of the light shielding film 20 with respect to a polar solution may be increased. However, the increased effect of compatibility through UV light irradiation is temporary. Moreover, increase in compatibility is limited and it is difficult to remove a polar solution remaining on the surface of the light shielding film 20 after a cleaning process. To solve such problems, compatibility with respect to a polar solution of the light shielding film 20 may be controlled before the light irradiation in the present disclosure.

In detail, when the compatibility of the light shielding film 20 with respect to a polar solution is not controlled before UV light irradiation, the surface of the light shielding film 20 may not have sufficient compatibility to the polar solution even though the UV light irradiation has been performed. In addition, compatibility between particles such as an organic material and the surface of the light shielding film 20 may be increased, and thereby the effect of cleaning may be degraded.

On the other hand, when compatibility of the light shielding film 20 with respect to a polar material is adjusted only in consideration of the cleaning effect of the light shielding film 20, even after the effect of increasing compatibility caused from the UV light irradiation disappears, the surface of the light shielding film can still show a characteristic of relatively high compatibility to a polar solution. This may cause a trouble in removing the polar solution remaining on the surface of the light shielding film 20 after a cleaning process. When the polar solution remaining on the surface of the light shielding film 20 is not effectively removed, damage due to reaction of the remaining solution with the surface of the light shielding film 20 may occur on the surface of the light shielding film 20.

The present disclosure may control the SA1 value for the light shielding film 20 to have adjusted compatibility with respect to a polar material before UV light irradiation. Through this, the light shielding film 20 treated through the UV light irradiation can have excellent cleaning effect in the cleaning process. Simultaneously, the occurrence of damage on the surface of the light shielding film due to the remaining polar solution on the surface of the light shielding film can be substantially suppressed.

The SA1 value of the light shielding film 20 may be controlled by various factors such as thermal treatment after the formation of the light shielding film 20, conditions of cooling treatment and a stabilizing operation, sputtering condition of forming the light shielding film 20, and the like. The detailed description of a controlling method of SA1 value is overlapped with the content below and thus omitted.

The γ_{SL} value and tan θ value are measured through Goniometer method by using a surface analysis device. In detail, the surface of the light shielding film 20 is divided into a total of nine sectors by trisection in the width and trisection in the length. A pure water of 0.8 to 1.2 μL, or 1 μL as one example is dropped to the center of each sector with an interval of about 2 seconds, and the contact angle of pure water in each sector is measure by using a surface analysis device. The contact angle of the light shielding film 20 measured with a pure water is calculated from an average value of the contact angle values measured in each sector. After 2 seconds after completion of dropping a pure water, diiodo-methane of 0.8 to 1.2 μL, or 1 μL as one example is dropped to a position spaced apart from the position, where the pure water has been dropped, with an interval of about 2 seconds, and the contact angle of diiodo-methane of each sector is measured by using a surface analysis device. The contact angle of the light shielding film 20 measured by diiodo-methane is calculated from an average value of the contact angle values measured in each sector. The surface energy and tan θ value are calculated from the contact angle of the pure water and the diiodo-methane measured from the light shielding film 20.

For example, the γ_{SL} value and tan θ value can be measured through MSA (Mobile Surface Analyzer) double type available from KRUSS corporation.

Surface energy of the pure water used in the measurement is 72.8 mN/m, the polar component within the surface energy is 51 mN/m, and the dispersant component is 21.8 mN/m. Surface energy of the diiodo-methane used in the measurement is 50.8 mN/m, the polar component within the surface energy is 0 mN/m, and the dispersant component is 50.8 mN.

The γ_{SL} value according to Equation 2-1 (Young's equation) below is calculated from the surface energy (γ_{SG}) and θ value, and the SA1 value according to the Equation 1-1 above is calculated from the γ_{SL} value and tan θ value.

γ_{SG}=γ_{SL}+γ_{LG}×cos θ [Equation 2-1]

In the Equation 2-1, the γ_{SL} value is the surface energy of the light shielding film, the θ_{SL} value is the interfacial energy between the light shielding film and a pure water, and the γ_{SL} value is the surface energy of a pure water.

The SA1 value of the light shielding film 20 may be 60 to 90 mN/m. The SA1 value of the light shielding film 20 may be 64 to 90 mN/m. The SA1 value of the light shielding film 20 may be 70 to 88 mN/m. The SA1 value of the light shielding film 20 may be 80 to 87 mN/m. In such a case, cleaning effect of the light shielding film 20 after UV light irradiation can be sufficiently increased. Also, damage on the surface of the light shielding film 20, which can occur after the cleaning process, can be effectively suppressed.

The θ value may be 70° or more. The θ value may be 72° or more. The θ value may be 74° or more. The θ value may be 85° or less. The θ value may be 75° or less. The θ value may be 74.5° or less. In such a case, solution with a relatively high polarity remaining on the surface of the light shielding film 20 after a cleaning process can be effectively removed.

The γ_{SL} value may be 22 mN/m or more. The γ_{SL} value may be 22.5 mN/m or more. The γ_{SL} value may be 23 mN/m or more. The γ_{SL} value may be 25 mN/m or less. The γ_{SL} value may be 24.5 mN/m or less. The γ_{SL} value may be 24 mN/m or less. In such a case, the surface of the light shielding film 20 can be effectively cleaned through a cleaning process, and damage of the light shielding film 20 caused from a polar solution remaining on the surface of the light shielding film 20 after the cleaning process can be substantially prevented.

The surface energy of the light shielding film 20 is calculated by combining the polar component and the dispersant component within the surface energy.

The surface energy of the light shielding film 20 may be 42 to 47 mN/m.

In such a light shielding film 20, the particles present on the surface of the light shielding film can be easily removed through a cleaning process. Also, the polar solution remaining on the surface of the light shielding film 20 can be further easily removed after the cleaning process is completed.

The surface energy of the light shielding film 20 can be controlled depending on a surface profile of the light shielding film 20, amounts of elements included in the light shielding film 20, condition of post treatment for light shielding film 20, and the like. Detailed description for controlling the surface energy of the light shielding film 20 is overlapped with content below and thus omitted.

A method of measuring a surface energy of a light shielding film 20 is the same as the method described above and thus the further description is omitted.

The surface energy of the light shielding film 20 may be 42 to 47 mN/m. The surface energy of the light shielding film 20 may be 43 to 46 mN/m. The surface energy of the light shielding film 20 may be 43.2 to 44 mN/m. In such a case, particles attached to the surface of the light shielding film 20 can be easily removed through a cleaning process, and damage of the light shielding film 20 caused from the polar solution remaining on the surface of the light shielding film 20 after being cleaned can be suppressed.

The ratio of polar component of the surface energy compared to the surface energy of the light shielding film 20 may be 0.135 to 0.16.

Compatibility between the surface of the light shielding film and the polar solution is also affected by the ratio of polar component within the surface energy as well as the surface energy of the light shielding film. In detail, even though the surfaces of two or more light shielding films have the same surface energy from each other, respective light shielding films can have different compatibility from each other depending on the ratio of polar component compared to the entire surface energy. The present disclosure can control a surface energy and simultaneously can control the ratio of polar component to the entire surface energy. Through this, an organic material or the like remaining on the surface of the light shielding film can be effectively removed through a cleaning process with a polar solution. Also, the polar solution remaining on the surface of the light shielding film after cleaning can be effectively removed.

The ratio of polar component of the surface energy compared to the surface energy of the light shielding film 20 may be 0.135 to 0.16. The ratio of polar component of the surface energy compared to the surface energy of the light shielding film 20 may be 0.137 to 0.155. The ratio of polar component of the surface energy compared to the surface energy of the light shielding film 20 may be 0.138 to 0.15. In such a case, particles formed on the surface of the light shielding film and the like can be effectively removed through cleaning, and a polar solution remaining on the surface of the light shielding film 20 can be easily removed.

The SA2 value of the light shielding film is a parameter reflecting compatibility between hydrophobic materials and the surface of the light shielding film.

The SA2 value of the light shielding film according to Equation 1-2 below may be 6.5 to 8:

SA2=γ_{SLd}×tan θ_{d} [Equation 1-2]

In the Equation 1-2, the γ_{SLd} is an interfacial energy between the light shielding film and diiodo-methane, and the ed is a contact angle of the light shielding film measured by diiodo-methane.

The γ_{SLd} value according to Equation 2-2 (Young's equation) below is calculated from the surface energy (γ_{SG}) and θ_{d} value of the light shielding film, and the SA2 value according to the Equation 1-2 is calculated from the γ_{SLd} value and tan θ_{d} value.

γ_{SG}=γ_{SLd}+γ_{LGd}×cos θ_{d} [Equation 2-2]

In the Equation 2-2, the γ_{SG} value is a surface energy of the light shielding film, and the γ_{SLd} value is an interfacial energy between the light shielding film and diido-methane, the γ_{LGd} value is a surface energy of diido-methane.

The SA2 value of the light shielding film may be 6.5 to 8. In such a case, an organic material, that is nonpolar particles, can be easily removed from the surface of the light shielding film.

### Layer Structure and Composition of Light Shielding Film

FIG. 2 is a conceptual view for illustrating a blank mask 100 according to another embodiment. With reference to the FIG. 2, the embodiment will be described.

The light shielding film 20 may include a first light shielding layer 21 and a second light shielding layer 22 disposed on the first light shielding layer 21.

The second light shielding layer 22 may include a transition metal and at least one of oxygen and nitrogen. The second light shielding layer 22 may include a transition metal in an amount of 50 to 80 at %. The second light shielding layer 22 may include a transition metal in an amount of 55 to 75 at %. The second light shielding layer 22 may include a transition metal in an amount to 60 to 70 at %.

The amount of oxygen or nitrogen of the second light shielding layer 22 may be 10 to 35 at %. The amount oxygen or nitrogen of the second light shielding layer 22 may be 15 to 25 at %.

The second light shielding layer 22 may include nitrogen in an amount of 5 to 20 at %. The second light shielding layer 22 may include nitrogen in an amount of 7 to 13 at %.

In such a case, it is possible to help the light shielding film 20 to shield an exposure light substantially with a phase shift film 30 together.

A first light shielding layer 21 may include a transition metal, oxygen, and nitrogen. The first light shielding layer 21 may include a transition metal in an amount of 30 to 60 at %. The first light shielding layer 21 may include a transition metal in an amount of 35 to 55 at %. The first light shielding layer 21 may include a transition metal in an amount of 40 to 50 at %.

The sum of the oxygen amount and the nitrogen amount of the first light shielding layer 21 may be 40 to 70 at %. The sum of the oxygen amount and the nitrogen amount of the first light shielding layer 21 may be 45 to 65 at %. The sum of the oxygen amount and the nitrogen amount of the first light shielding layer 21 may be 50 to 60 at %.

The first light shielding layer 21 may include oxygen in an amount of 20 to 40 at %. The first light shielding layer 21 may include oxygen in an amount of 23 to 33 at %. The first light shielding layer may include oxygen in an amount of 25 to 30 at %.

The first light shielding layer 21 may include nitrogen in an amount of 5 to 20 at %. The first light shielding layer 21 may include nitrogen in an amount of 7 to 17 at %. The first light shielding layer 21 may include nitrogen in an amount of 10 to 15 at %.

In such a case, the first light shielding layer 21 can help the light shielding film 20 to have an excellent extinction characteristic.

The transition metal may include at least one selected from the group consisting of Cr, Ta, Ti, and Hf. The transition metal may be Cr.

The thickness of the first light shielding layer 21 may be 250 to 650 Å. The thickness of the first light shielding layer 21 may be 350 to 600 Å. The thickness of the first light shielding layer 21 may be 400 to 550 Å. In such a case, the first light shielding layer 21 may help the light shielding film 20 to block an exposure light effectively.

The thickness of the second light shielding layer 22 may be 30 to 200 Å. The thickness of the second light shielding layer 22 may be 30 to 100 Å. The thickness of the second light shielding layer 22 may be 40 to 80 Å. In such a case, the second light shielding layer 22 can contribute to the extinction characteristic of the light shielding film 20 to be improved. In addition, a side shape of the light shielding pattern film 25 formed through patterning can be further elaborately controlled.

A ratio of the thickness of the second light shielding layer 22 compared to the thickness of the first light shielding layer 21 may be 0.05 to 0.3. The ratio may be 0.07 to 0.25. The ratio may be 0.1 to 0.2. In such a case, the light shielding film 20 can have a sufficient extinction characteristic. Furthermore, the side surface of the patterned light shielding film can be formed to be close to be perpendicular to the surface of the transparent substrate.

The amount of a transition metal of the second light shielding layer 22 may be greater than the amount of a transition metal of the first light shielding layer 21.

The second light shielding layer 22 may have a greater amount of a transition metal than the first light shielding layer. This is for controlling the side surface profile of the light shielding pattern film 25 elaborately and the light shielding film having a reflexibility demanded in a defect inspection or the like. However, in such a case, during thermal treatment for the light shielding film 20, recovery, recrystallization, and growth of a grain of a transition metal may occur in the second light shielding layer 22. When the growth of the grain is not controlled in the second light shielding layer 22 including a transition metal in a high amount, the surface of the light shielding film 20 may have further rough outline due to the particles of a transition metal grown excessively. The surface affect compatibility between the light shielding film 20 and a polar solution and may cause a problem in removing a polar solution remaining on the surface of the light shielding film 20 after a cleaning process.

The present disclosure controls the SA1 value of the light shielding film 20 within a predetermined range, while the amount of a transition metal of the second light shielding layer 22 is greater than the amount of a transition metal of the first light shielding layer 21, and thereby can allow the light shielding film 20 to have desired optical properties and etching characteristics. Simultaneously, damage on the surface of the light shielding film 20 caused from a polar solution remaining on the surface of the light shielding film 20 can be effectively suppressed.

### Optical Properties of Light Shielding Film

A transmittance of the light shielding film 20 with respect to a light with a wavelength of 193 nm may be 1% or more. The transmittance of the light shielding film 20 with respect to a light with a wavelength of 193 nm may be 1.3% or more. The transmittance of the light shielding film 20 with respect to a light with a wavelength of 193 nm may be 1.4% or more. The transmittance of the light shielding film 20 with respect to a light with a wavelength of 193 nm may be 2% or less.

The light shielding film 20 may have an optical density of 1.8 or more with respect to a light with a wavelength of 193 nm. The light shielding film 20 may have an optical density of 1.9 or more with respect to a light with a wavelength of 193 nm. The light shielding film 20 may have an optical density of 3 or less with respect to a light with a wavelength of 193 nm.

In such a case, a thin film including a light shielding film 20 can effectively suppress the transmission of an exposure light.

### Other Thin Film

FIG. 3 is a conceptual view for illustrating a blank mask according to another embodiment of the present disclosure. With reference to FIG. 3, a blank mask of an embodiment will be described.

A blank mask 100 according to another embodiment of the present specification includes a transparent substrate 10, a phase shift film 30 disposed on the transparent substrate 10 and a light shielding film 20 disposed on the phase shift film 30.

The phase shift film 30 may include a transition metal and silicon.

The light shielding film 20 may include a transition metal, and at least one of oxygen and nitrogen.

A contact angle of the light shielding film 20 measured with a pure water is 70° or more.

The phase shift film 30 may be disposed between the transparent substrate 10 and the light shielding film 20. The phase shift film 30 is a thin film, which attenuates the strength of an exposure light transmitting the phase shift film 30, adjusts the phase shift, and thereby substantially suppresses a diffraction light occurring at the edge of a pattern.

The phase shift film 30 may have a phase difference of 170 to 190° with respect to a light with a wavelength of 193 nm. The phase shift film 30 may have a phase difference of 175 to 185° with respect to a light with a wavelength of 193 nm. The phase shift film 30 may have a transmittance of 3 to 10% with respect to a light with a wavelength of 193 nm. The phase shift film 30 may have a transmittance of 4 to 8% with respect to a light with a wavelength of 193 nm. In such a case, the resolution of a photomask 200 including the phase shift film 30 may be improved.

The phase shift film 30 may include a transition metal and silicon. The phase shift film 30 may include a transition metal, silicon, oxygen, and nitrogen. The transition metal may be molybdenum.

The descriptions of the properties and the composition of the transparent substrate 10 and the light shielding film 20 are overlapped with the above descriptions, respectively, and thus omitted.

A hard mask (not shown) may be disposed on the light shielding film 20. The hard mask may function as an etching mask film when a pattern of the light shielding film 20 is etched. The hard mask may include silicon, nitrogen, and oxygen.

### Photomask

FIG. 4 is a conceptual view for illustrating a photomask according to another embodiment of the present disclosure. With reference to the FIG. 4, the photomask of the embodiment will be described.

The photomask 200 according to another embodiment of the present disclosure may include a transparent substrate 10 and a light shielding pattern film 25 disposed on the transparent substrate 10.

The light shielding pattern film 25 may include a transition metal, and at least one of oxygen and nitrogen.

A PSA1 value of the light shielding pattern film 25 according to Equation 3 below is 60 to 90 mN/m:

PSA1=γ_{PSL}×tan θ_{P} [Equation 3]

In the Equation 3, the γ_{PSL} is an interfacial energy between an upper surface of the light shielding pattern film 25 and pure water, and the θ_{P} is a contact angle of the upper surface of the light shielding pattern film 25 measured with a pure water.

The light shielding pattern film 25 may be formed by patterning the light shielding film 20 of the blank mask 100 described above.

A method of measuring a PSA1 value of the light shielding pattern film 25 is the same as the method of measuring an SA1 value of the light shielding film 20 in the blank mask 100, except for the measuring target, which is an upper surface of the light shielding pattern film 25, not the surface of the light shielding film 20.

When the PSA1 value of the light shielding pattern film 25 is measured, a pure water and diiodo-methane are dropped to contact with the upper surface of the light shielding pattern film 25.

When the upper surface of the light shielding pattern film 25 is not disposed at the center within each sector of the upper surface of the blank mask, the γ_{PSL} value and θ_{P} value are measured on the upper surface of the light shielding pattern film 25 placed near to the center.

The descriptions of the properties, composition, and structure of the light shielding pattern film 25 are overlapped with the description of the light shielding film 20 of the blank mask 100 and thus omitted.

### Manufacturing Method of Light Shielding Film

The method of manufacturing the blank mask according to one embodiment may include a preparing operation of installing a transparent substrate and a sputtering target in a sputtering chamber.

The method may include a film formation operation of injecting an atmosphere gas in a sputtering chamber, supplying an electric power to a sputtering target, and thereby forming a light shielding film on the transparent substrate.

The film formation operation may include forming a first light shielding layer and forming a second light shielding layer on the first light shielding layer.

The method may include a thermal treatment operation of thermally treating the light shielding film for 5 to 30 minutes at 150 to 330° C.

The method may include a cooling operation of cooling the light shielding film after the thermal treatment operation.

The method may include a stabilizing operation of stabilizing the light shielding film after passing the cooling operation at 15 to 30° C.

In the preparing operation, a sputtering target may be selected in consideration of the composition of the light shielding film when the light shielding film is formed. One target containing a transition metal may be used as the sputtering target. Two or more targets including one target containing a transition metal may be used as the sputtering target. The sputtering target containing a transition metal may include a transition metal in an amount of 90 at % or more. The sputtering target containing a transition metal may include a transition metal in an amount of 95 at % or more. The target sputtering containing a transition metal may include a transition metal in an amount of 99 at % or more.

The transition metal may include at least one selected from the group consisting of Cr, Ta, Ti, and Hf. The transition metal may include Cr.

The description of a transparent substrate 10 disposed in a sputtering chamber is overlapped with the above description and thus omitted.

In the preparing operation, a magnet may be disposed in a sputtering chamber. The magnet may be disposed on the opposite side to one surface, where a sputtering occurs within a sputtering target.

In the light shielding film forming operation, different film formation process conditions may be applied to respective layers included in the light shielding film. Particularly, in consideration of compatibility between the light shielding film and a polar solution, an extinction characteristic and an etching characteristic of the light shielding film, and the like, various process conditions such as the composition of the atmosphere gas, an electric power supplied to the sputtering target, the time for film formation time, and the like may be differently applied to respective layers.

The atmosphere gas may include an inert gas, a reactive gas, and a sputtering gas. The inert gas is a gas not including the elements contained in the thin film to be formed. The reactive gas is a gas including the elements contained in the thin film to be formed. The sputtering gas is a gas ionized in a plasma atmosphere and collided with the target.

The inert gas may include helium.

The reactive gas may include a gas including nitrogen. The gas including nitrogen may be for example, N₂, NO, NO₂, N₂O, N₂O₃, N₂O₄, N₂O₅ or the like. The reactive gas may include a gas including oxygen. The gas including oxygen may be for example, O₂, CO₂, or the like. The reactive gas may include a gas including nitrogen and a gas including oxygen. The reactive gas may include a gas including both nitrogen and oxygen. The gas including both nitrogen and oxygen may be for example, NO, NO₂, N₂O, N₂O₃, N₂O₄, N₂O₅ or the like.

The sputtering gas may be Ar gas.

A power source for supplying an electric power to the sputtering target may be a DC power source, or an RF power source.

In the film formation process of the first light shielding layer, an electric power supplied to the sputtering target may be applied to be 1.5 to 2.5 kW. In the film formation process of the first light shielding layer, an electric power supplied to the sputtering target may be applied to be 1.6 to 2 kW.

In the film formation process of the first light shielding layer, the ratio of the flow rate of a reactive gas compared to the flow rate of an inert gas in an atmosphere gas may be 1.5 to 3. The ratio may be 1.8 to 2.7. The ratio may be 2 to 2.5.

The ratio of the oxygen amount compared to the nitrogen amount included in the reactive gas may be 1.5 to 4. The ratio may be 2 to 3. The ratio may be 2.2 to 2.7.

In such a case, the first light shielding layer may help the light shielding film to have a sufficient extinction characteristic, and the etching characteristic of the first light shielding layer may be controlled for the side surface of a patterned light shielding film to have a shape close to be perpendicular to a surface of the transparent substrate.

A film formation time of the first light shielding layer may be 200 to 300 seconds. The film formation time may be 210 to 240 seconds. In such a case, the first light shielding layer may help the light shielding film 20 to have a sufficient extinction characteristic.

In the film formation process of the second light shielding layer, an electric power supplied to a sputtering target may be 1 to 2 kW. In the film formation time of the second light shielding layer, an electric power supplied to a sputtering target may be 1.2 to 1.7 kW.

In the film formation process of the second light shielding layer, the ratio of the flow rate of a reactive gas compared to the flow rate of an inert gas in an atmosphere gas may be 0.3 to 0.8. The ratio may be 0.4 to 0.6.

In the film formation process of the second light shielding layer, the ratio of the oxygen amount compared to the nitrogen amount included in the reactive gas may be 0.3 or less. The ratio may be 0.1 or less. The ratio may be 0.001 or more.

In such a case, it can help to control compatibility of the light shielding film with respect to a polar solution within a range desired in the embodiment. Also, it is possible to help the light shielding film to have a stable extinction characteristic.

The film formation time of a second light shielding layer may be 10 to 30 seconds. The film formation time may be 15 to 25 seconds. In such a case, the second light shielding layer can help to suppress the transmission of an exposure light.

In the thermal treatment operation, the light shielding film after the film formation operation may be treated by heat. In detail, the substrate, on which the light shielding film has been formed, is disposed in a thermal treatment chamber, and after that, thermal treatment may be performed.

In the cooling operation, the light shielding film after thermal treatment may be cooled. On the side of the substrate of a blank mask after the thermal treatment, a cooling plate, which has been adjusted to have a cooling temperature predetermined in the embodiment, may be disposed to cool the blank mask. In the cooling operation, space between the blank mask and the cooling plate is adjusted, an atmosphere gas is introduced, and thereby the cooling rate of the blank mask may be controlled.

For removing stress formed in the light shielding film and further improving density of the light shielding film, thermal treatment may be required to the light shielding film. When thermal treatment is applied to the light shielding film, the transition metal included in the light shielding film goes through recovery and recrystallization, and the stress formed in the light shielding film can be effectively removed. However, in the thermal treatment operation, when the temperature and time for thermal treatment are not controlled, grain grows in the light shielding film, and the surface of the light shielding film may become rougher than the surface before thermal treatment, due to the grain composed by a transition metal, whose size is not controlled.

Compatibility of the light shielding film with respect to a polar solution may also be affected by physical properties such as surface roughness of the light shielding film as well as chemical properties such as the composition of the light shielding film. Accordingly, when deformation of the surface outline of the light shielding film occurs after thermal treatment, compatibility of the light shielding film with respect to a polar solution may be increased. Due to this, it may be difficult to remove a cleaning solution remaining on the surface of the light shielding film after the cleaning.

The embodiment may control the time and temperature for thermal treatment in the thermal treatment operation, and in a subsequent cooling operation, the cooling rate, cooling time, the flow rate of an atmosphere gas during cooling, and the like can be controlled. Through this, the internal stress formed in the light shielding film can be effectively removed, and the fluctuation of compatibility of the light shielding film with respect to a polar solution due to thermal treatment can be controlled.

The thermal treatment operation may be performed at 150 to 330° C. The thermal treatment operation may be performed at 180 to 300° C.

The thermal treatment operation may be performed for 5 to 30 minutes. The thermal treatment operation may be performed for 10 to 20 minutes.

In such a case, the internal stress in the light shielding film can be effectively removed, and it is possible to help excessive growth of the particles of a transition metal due to thermal treatment within the light shielding film to be suppressed.

A cooling operation may be performed within 2 minutes from the time when the thermal treatment operation is completed. In such a case, the growth of transition metal particles due to residual heat within the light shielding film can be effectively prevented.

A pin having a predetermined length may be installed in each edge of a cooling plate, and a blank mask may be disposed on the pin to have the lower surface of the transparent substrate facing the cooling plate, and the cooling rate of the blank mask can be controlled.

In addition to the cooling plate, an inert gas is injected to a space, where the cooling operation proceeds, and thereby the cooling rate of the blank mask can be further increased. Through the inert gas, the residual heat within the light shielding film can be further effectively removed.

Particularly, in the blank mask, cooling efficiency may be slightly decreased on the upper surface side of the light shielding film by the cooling substrate compared to the substrate. Through the injection of the inert gas, the residual heat of the upper surface side of the light shielding film can be further effectively removed. The inert gas may be for example, helium.

In the cooling operation, the cooling temperature of the cooling plate may be 10 to 30° C. The cooling temperature may be 15 to 25° C.

In the cooling operation, a distance between the blank mask and the cooling plate may be 0.01 o 30 mm. The distance may be 0.05 to 5 mm. The distance may be 0.1 to 2 mm.

In the cooling operation, a cooling rate of the blank mask may be 10 to 80° C./min. The cooling rate may be 20 to 75° C./min. The cooling rate may be 40 to 70° C./min.

In such a case, growth of a transition metal grain due to residual heat within the light shielding film after thermal treatment may be suppressed, and the polar solution remaining on the surface of the light shielding film after a cleaning process can be easily removed.

In the stabilizing operation, the blank mask after the cooling operation may be stabilized. In the case of a blank mask after the cooling operation, considerable damage may be added to the blank mask due to rapid temperature change. To prevent this, a stabilizing operation may be required.

The method for stabilizing the blank mask after the cooling operation may be various. As one example, the blank mask after the cooling operation is detached from the cooling plate, and subsequently can be left for a certain time in the atmosphere at room temperature. As another example, the blank mask after the cooling operation is detached from the cooling plate, and subsequently may be rotated for 10 to 60 minutes at 15 to 30° C. to be stabilized. At this time, the blank mask may be rotated at 20 to 50 rpm. As another example, a gas with a low reactivity with respect to the light shielding film may be injected to the blank mask after the cooling operation for 1 to 5 minutes in the flow rate of 5 to 10 L/min. At this time, the temperature of the gas may be 20 to 40° C.

### Method of Manufacturing Semiconductor Element

A method of manufacturing the semiconductor element according to another embodiment of the present disclosure includes a preparing operation of disposing a light source, a photomask, and a semiconductor wafer, on which a resist film have been applied, an exposure operation of selectively transmitting a light incident from the light source through the photomask on the semiconductor wafer to be transferred, and a developing operation of developing a pattern on the semiconductor wafer.

The photomask includes a transparent substrate and a light shielding pattern film disposed on the transparent substrate.

The light shielding pattern film may include a transition metal, and at least one of oxygen and nitrogen.

The PSA1 value of the light shielding pattern film according to Equation 3 below may be 60 to 90 mN/m:

PSA1=γ_{PSL}×tan θ_{P} [Equation 3]

In the Equation 3, the γ_{PSL} is an interfacial energy between an upper surface of the light shielding pattern film and a pure water, and the θ_{P} is a contact angle of the upper surface of the light shielding pattern film measured with the pure water.

In the preparing operation, the light source is a device, which can generate an exposure light with a short wavelength. The exposure light may be a light with a wavelength of 200 nm or less. The exposure light may be an ArF light with a wavelength of 193 nm.

A lens may be disposed additionally between the photomask and the semiconductor wafer. The lens may scale down the pattern shape in the photomask and transfer it on the semiconductor wafer. The lens is not limited if the lens may be applied to an exposure process of an ArF semiconductor wafer. For example, the lens may be composed of calcium fluoride (CaF2).

In the exposure operation, the exposure light may be selectively transmitted on the semiconductor wafer through a photomask. In such a case, chemical transformation may occur in the portion, where the exposure light is incident within the resist film.

In the developing operation, a pattern may be developed on the semiconductor wafer by treating the semiconductor wafer after the exposure operation with a developing solution. When the resist film is a positive resist, the portion exposed to the exposure light within the resist film may be dissolved by a developing solution. When the resist film is a negative resist, the portion not exposed to the exposure light within the resist film may be dissolved by a developing solution. The resist film is formed into a resist pattern by treatment of a developing solution. By taking the resist pattern as a mask, a pattern may be formed on the semiconductor wafer.

The description of the photomask is overlapped with the above description and thus omitted.

Hereinafter, further detailed description of specific example embodiments will be made.

### Manufacture Example: Formation of Light Shielding Film

Example 1: A transparent substrate of quartz material with a width of 6 inches, a length of 6 inches, and a thickness of 0.25 inches was disposed in a chamber of a DC sputtering device. A chrome target was disposed in the chamber to form a T/S distance of 255 mm and an angle of 25 degrees between the substrate and the target.

Thereafter, an atmosphere gas, in which Ar of 21 volume %, N₂ of 11 volume %, CO₂ of 32 volume %, and He of 36 volume % had been mixed, was introduced into the chamber, the electric power supplied to the sputtering target was 1.85 kW, the rotation speed of a magnet 113 rpm, and a sputtering process was performed for 250 seconds, thereby forming a first light shielding layer.

After forming the first light shielding layer, an atmosphere gas, in which Ar of 57 volume % and N₂ of 43 volume % had been mixed, was introduced into the chamber, the electric power supplied to a sputtering target was 1.5 kW, a sputtering process was performed for 25 seconds, and a blank mask sample, in which a second light shielding layer had been formed, was manufactured.

The sample after forming the second light shielding layer was disposed in a thermal treatment chamber, and thermal treatment was performed for 15 minutes at the atmosphere temperature of 200° C.

A cooling plate, to which a cooling temperature had been applied to be 23° C., was installed on the lower side of the transparent substrate of the sample after thermal treatment. The distance between the substrate and the cooling plate of the sample was adjusted to have a cooling rate of 36° C./min measured at the upper surface of the light shielding film of the sample, and after that, the cooling operation was performed for 5 minutes.

After the cooling treatment, the sample was left at an atmosphere of 20 to 25° C. and stabilized for 15 minutes.

Example 2: A blank mask sample was manufactured under the same condition as Example 1. However, after the formation of the light shielding film, the sample was treated with heat at 250° C., cooling treatment was performed for 7 minutes, and the sample treated by cooling was stabilized for 20 minutes.

Example 3: A blank mask sample was manufactured under the same condition as Example 1. However, after the formation of the light shielding film, the sample was treated with heat at 250° C., the cooling temperature of the sample was 30° C./min and thereby cooling treatment was performed for 8 minutes.

Example 4: A blank mask sample was manufactured under the same condition as Example 1. However, after the formation of the light shielding film, the sample was treated with heat at 300° C., the cooling treatment of the sample after the thermal treatment was performed for 8 minutes, and the sample treated by cooling was stabilized for 30 minutes.

Example 5: A blank mask sample was manufactured under the same condition as Example 1. However, after the formation of the light shielding film, the sample was treated with heat at 300° C., a helium gas was injected in the flow rate of 300 sccm to the sample to have a cooling rate of 56° C./min, and the sample treated by cooling was stabilized for 45 minutes.

Comparative Example 1: A blank mask sample was manufactured under the same condition as Example 1. However, thermal treatment, cooling treatment, and stabilization were not performed to the sample.

Comparative Example 2: A blank mask sample was manufactured under the same condition as Example 1. However, after the formation of the light shielding film 20, the sample was thermally treated at 250° C., and when treated by cooling, the sample was naturally cooled in the atmosphere without use of a cooling plate. During the natural cooling, the atmosphere temperature of 23° C., the cooling time of 120 minutes, the cooling rate of 2° C./min measured in the sample were applied. After the cooling treatment, stabilization was not performed.

Comparative Example 3: A blank mask sample was manufactured under the same condition of Example 1. However, the sample was thermally treated at 300° C., and during cooling treatment, a helium gas was injected in the flow rate of 300 sccm to the sample to have a cooling rate of 56° C./min. Stabilization was not performed for the sample treated by cooling.

The conditions of thermal treatment, cooling treatment, and stabilization of respective Examples and Comparative Examples were described in Table 1 below.

Evaluation Example: Measurement of SA1 Value of Light Shielding Film

The surface of the light shielding film of each Example or Comparative Example was trisected in the width and the length, and thereby divided into a total of nine sectors. Pure water of 0.8 to 1.2 μL, for examplel μL, was dropped to the center of each sector with an interval of about 2 seconds, and the contact angle of the pure water in each sector was measured by a surface analysis device. The contact angle (θ) of the light shielding film measured with the pure water was calculated from the average value of the contact angle values measured from each sector. Diiodo-methane of 1 θL was dropped with an interval of about 2 seconds to the position spaced apart from the position, where the pure water was dropped, and the contact angle of diiodo-methane in each sector was measured by a surface analysis device. The contact angle (θd) of the light shielding film measured with diiodo-methane was calculated from the average value of the contact angle values measured from each sector.

From the calculated contact angle, the surface energy (γ_{SG}) value of the light shielding film, polar component and dispersant component within the surface energy (γ_{SG}) of the light shielding film, the ratio of polar component compared to the surface energy of the light shielding film and tan θ values of Examples or Comparative Examples were measured or calculated through a surface analysis device, from the calculated contact angle.

Thereafter, γ_{SL} value according to Equation 2-1 was calculated from the surface energy (γ_{SG}) value and tan θ value calculated for Examples or Comparative Examples, and SA1 value according to Equation 1-1 was calculated from γ_{SL} value and tan θ value.

Also, γ_{SLd} value according to Equation 2-2 was calculated from the surface energy (γ_{SG}) value and tan θ_{d} value calculated for Examples or Comparative Examples, and SA2 value according to Equation 1-2 was calculated from γ_{SLd} value and tan θ_{d} value.

As the surface analysis device, MSA (Mobile Surface Analyzer) double type model available from KRUSS corporation was used.

The measured values of Examples or Comparative Examples were described in Tables 2 and 3.

### Evaluation Example: Evaluation of Cleaning Effect of Light Shielding Film

Using a validator of M6641S model available from LASERTEC corporation, Examples or Comparative Examples were inspected to check whether particles were formed on the light shielding film before cleaning.

After the measurement, the surface of the light shielding film of each sample was irradiated for 120 seconds by a light with a wavelength of 172 nm. Immediately after finishing the irradiation, each sample was rotated at 80 rpm and simultaneously SC-1 solution was injected in flow rate of 600 ml/min on the surface of the light shielding film of the sample for 8 to 10 minutes. The SC-1 solution is a solution including NH₄OH of 14.3 wt %, H₂O₂ of 14.3 wt %, and H₂O of 71.4 wt %.

After the cleaning, Using a validator of M6641S model available from LASERTEC corporation, Examples or Comparative Examples were inspected to check whether particles were formed on the light shielding film. Comparing with the light shielding film before cleaning, when particles newly added after the cleaning were not found, it was evaluated as O, and when particles added newly after the cleaning were found, it was evaluated as X.

The results of evaluation by Example or Comparative Example were described in Table 3 below.

TABLE 1

| | Temperature | Thermal | Whether | The Flow | Temperature | | | | |
|---|---|---|---|---|---|---|---|---|---|
| | of Thermal | Treatment | Cooling | rate of | of Cooling | Cooling | | Temperature of | Stabilization |
| | Treatment | Time | Plate Is | Helium Gas | Plate | Time | Cooling Speed | Stabilization | Time |
| | (° C.) | (Minute) | Used | (sccm) | (° C.) | (Minute) | (° C./Minute) | (° C.) | (Minute) |
| Example 1 | 200 | 15 | ◯ | — | 23 | 5 | 36 | 20 to 25 | 15 |
| Example 2 | 250 | 15 | ◯ | — | 23 | 7 | 36 | 20 to 25 | 20 |
| Example 3 | 250 | 15 | ◯ | — | 23 | 8 | 30 | 20 to 25 | 15 |
| Example 4 | 300 | 15 | ◯ | — | 23 | 8 | 36 | 20 to 25 | 30 |
| Example 5 | 300 | 15 | ◯ | 300 | 23 | 5 | 56 | 20 to 25 | 45 |
| Comparative | — | — | X | — | — | — | — | — | — |
| Example 1 | | | | | | | | | |
| Comparative | 250 | 15 | X | — | 23 | 120 | 2 | — | — |
| Example 2 | | | | | (Atmosphere | | | | |
| | | | | | Temperature) | | | | |
| Comparative | 300 | 15 | ◯ | 300 | 23 | 5 | 56 | — | — |
| Example 3 | | | | | | | | | |

TABLE 2

| | | | | | | Dispersant |
|---|---|---|---|---|---|---|
| | | | | | Polar component | component |
| | | | | Surface | within Surface | within Surface |
| | | | | Energy of Light | Energy of Light | Energy of Light |
| | | γ_{SL} | | shielding Film | shielding Film | shielding Film |
| | SA1(mN/m) | (mN/m) | θ(°) | (mN/m) | (mN/m) | (mN/m) |
| Example 1 | 65.25 | 22.07 | 71.31 | 45.41 | 7.25 | 38.16 |
| Example 2 | 72.76 | 22.80 | 72.6 | 44.58 | 6.77 | 37.81 |
| Example 3 | 71.34 | 22.66 | 72.38 | 44.69 | 6.85 | 37.84 |
| Example 4 | 84.77 | 24.04 | 74.17 | 43.89 | 6.09 | 37.81 |
| Example 5 | 85.35 | 23.80 | 74.42 | 43.35 | 6.14 | 37.21 |
| Comparative | 53.08 | 21.11 | 68.31 | 48.02 | 8.13 | 39.89 |
| Example 1 | | | | | | |
| Comparative | 57.52 | 21.86 | 69.19 | 47.72 | 7.67 | 40.05 |
| Example 2 | | | | | | |
| Comparative | 95.01 | 24.62 | 75.47 | 42.89 | 5.71 | 37.18 |
| Example 3 | | | | | | |

TABLE 3

| | The Ratio | | | | |
|---|---|---|---|---|---|
| | of Polar | | | | |
| | component | | | | |
| | Compared to | | | | |
| | Surface | | | | |
| | Energy | | | | |
| | of Light | | | | |
| | shielding | SA2(mN/ | γ_{SLd}(mN/ | | Cleaning |
| | Film | m) | m) | θd(°) | Effect |
| Example | 0.160 | 7.55 | 8.15 | 42.83 | ◯ |
| 1 | | | | | |
| Example | 0.152 | 7.33 | 7.72 | 43.5 | ◯ |
| 2 | | | | | |
| Example | 0.153 | 7.39 | 7.81 | 43.44 | ◯ |
| 3 | | | | | |
| Example | 0.139 | 6.69 | 7.05 | 43.5 | ◯ |
| 4 | | | | | |
| Example | 0.142 | 7.10 | 7.19 | 44.62 | ◯ |
| 5 | | | | | |
| Comparative | 0.169 | 7.23 | 8.79 | 39.45 | X |
| Example | | | | | |
| 1 | | | | | |
| Comparative | 0.161 | 6.76 | 8.31 | 39.12 | X |
| Example | | | | | |
| 2 | | | | | |
| Comparative | 0.133 | 6.69 | 6.77 | 44.68 | X |
| Example | | | | | |
| 3 | | | | | |

In Table 2, while SA1 values of Examples 1 to 5 showed a value of 60 to 90 mN/m, SA1 values of Comparative Examples 1 to 3 showed a value of less than 60 mN/m or more than 90 mN/m.

While θ values of Examples 1 to 5 showed 70° or more, θ values of Comparative Examples 1 and 2 showed a value less than 70°.

While γ_{SL} value of Examples 1 to 5 showed 22 mN/m or more, γ_{SL} value of Comparative Examples 1 and 2 showed a value less than 22 mN/m.

For the surface energy of a light shielding film, while Examples 1 to 5 showed a value of 42 to 47 mN/m, the surface energy of the light shielding films 20 of Comparative Examples 1 and 2 showed a value more than 47 mN/m.

For the ratio of polar component compared to the surface energy of a light shielding film, while Examples 1 to 5 showed a value of 0.135 to 0.16, Comparative Examples 1 to 3 showed a value of less than 0.135 or more than 0.16.

For the cleaning effect, while Examples 1 to 5 gave a judgement of O, Comparative Examples 1 to 3 gave a judgement of X.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A blank mask comprising:
a transparent substrate and a light shielding film disposed on the transparent substrate,
wherein the light shielding film comprises a transition metal and at least one of oxygen and nitrogen, and
wherein the light shielding film has an SA1 value of 60 to 90 mN/m according to Equation 1-1:
SA1=γ_{SL}×tan θ [Equation 1-1]
where, in the Equation 1-1, the γ_{SL} is an interfacial energy between the light shielding film and a pure water and θ is a contact angle of the light shielding film measured with the pure water.

2. The blank mask of claim 1,
wherein the θ is 70° or more.

3. The blank mask of claim 1,
wherein the γ_{SL} is 22 mN/m or more.

4. The blank mask of claim 1,
wherein the light shielding film has a surface energy of 42 to 47 mN/m.

5. The blank mask of claim 4,
wherein the light shielding film has a ratio of 0.135 to 0.16 for polar component of the surface energy compared to the surface energy of the light shielding film.

6. The blank mask of claim 1,
wherein the light shielding film comprises a first light shielding layer and a second light shielding layer disposed on the first light shielding layer.

7. The blank mask of claim 6,
wherein an amount of the transition metal of the second light shielding layer is greater than an amount of the transition metal of the first light shielding layer.

8. The blank mask of claim 1,
wherein the transition metal comprises at least one selected from the group consisting of Cr, Ta, Ti, and Hf.

9. A blank mask comprising:
a transparent substrate, a phase shift film disposed on the transparent substrate, and a light shielding film disposed on the phase shift film,
wherein the phase shift film comprises a transition metal and silicon,
wherein the light shielding film comprises a transition metal and at least one of oxygen and nitrogen, and
wherein a contact angle of the light shielding film measured with a pure water is 70° or more.

10. The blank mask of claim 9,
wherein the γ_{SL} is 22 mN/m or more.

11. The blank mask of claim 9,
wherein the light shielding film has a surface energy of 42 to 47 mN/m.

12. The blank mask of claim 11,
wherein the light shielding film has a ratio of 0.135 to 0.16 for polar component of the surface energy compared to the surface energy of the light shielding film.

13. The blank mask of claim 9,
wherein the light shielding film comprises a first light shielding layer and a second light shielding layer disposed on the first light shielding layer.

14. The blank mask of claim 13,
wherein an amount of the transition metal of the second light shielding layer is greater than an amount of the transition metal of the first light shielding layer.

15. The blank mask of claim 9,
wherein the transition metal comprises at least one selected from the group consisting of Cr, Ta, Ti, and Hf.

16. A photomask comprising:
a transparent substrate and a light shielding pattern film disposed on the transparent substrate,
wherein the light shielding pattern film comprises a transition metal and at least one of oxygen and nitrogen, and
wherein the light shielding pattern film has a PSA1 value of 60 to 90 mN/m according to Equation 3 below:
PSA1=γ_{PSL}×tan θ_{P} [Equation 3]
where, in the Equation 3, γ_{PSL} is an interfacial energy between an upper surface of the light shielding pattern film and a pure water and θ_{P} is a contact angle of the upper surface of the light shielding pattern film measured with the pure water.

17. The photomask of claim 16,
wherein the light shielding pattern film comprises a first light shielding layer and a second light shielding layer disposed on the first light shielding layer.

18. The photomask of claim 17,
wherein an amount of the transition metal of the second light shielding layer is greater than an amount of the transition metal of the first light shielding layer.

19. The photomask of claim 16,
wherein the transition metal comprises at least one selected from the group consisting of Cr, Ta, Ti, and Hf.
